(19) United States
(12) Patent Application Publication
(10) Pub. No.: US 2017/0330984 A1
(43) Pub. Date: Nov. 16, 2017

(54) PHOTOVOLTAIC MODULE AND A METHOD FOR PRODUCING THE SAME

(71) Applicant: SOLIBRO RESEARCH AB, Uppsala (SE)

(72) Inventor: Olle LUNDBERG, Uppsala (SE)

(21) Appl. No.: 15/532,368

(22) PCT Filed: Nov. 27, 2015
(86) PCT No.: PCT/EP2015/077941

§ 371 Date: Jun. 1, 2017

(30) Foreign Application Priority Data
Dec. 3, 2014 (SE) 1451472-3

(51) Int. Cl. H01L 31/0465; H01L 31/0749; H01L 31/05; H01L 31/18; H01L 31/02

(52) U.S. Cl. CPC H01L 31/0465; H01L 31/1876; H01L 31/02021; H01L 31/0504; H01L 31/0749

(57) ABSTRACT

A photovoltaic module and a method for producing such modules is presented in which the resistance of the interconnects between neighboring photovoltaic cells is minimized and the dead-area is also minimized. This is achieved by routing the interconnects, in form of a finger, from a top contact of a first photovoltaic cell to a bottom contact of a second photovoltaic cell. The interconnect is isolated from the bottom contact of the first photovoltaic cell by means of the photovoltaic stack and the interconnect is connected to the bottom contact of the second photovoltaic cell in an opening of the photovoltaic stack.

### TECHNICAL FIELD

The present invention relates to a photovoltaic module, as well as a method for producing such a photovoltaic module. In particular, the present invention relates to a photovoltaic module with photovoltaic cells, which are connected by means of contact fingers, as well as a method for producing such photovoltaic modules.

### BACKGROUND

Due to the inherent nature of a photovoltaic cell, the available output voltage per cell is too low to be useful. Therefore, in order to achieve a useful output voltage, usually several photovoltaic cells are commonly connected in series. This series connection is for thin film solar cells usually performed by routing the top contact of a photovoltaic cell to a bottom contact of a neighboring photovoltaic cell. This way of connecting cells is often referred to as “monolithic integration”. A well-known problem associated with monolithic integration is that due to the routing a part of the area of the photovoltaic cell does not contribute to the photovoltaic conversion. Within the art, this part of the area is called the “dead-area”. For the performance of the solar cell it is important to minimize this dead area. Another loss in the monolithic interconnect is that the top transparent conductive oxide (TCO) layer needs to be relatively conductive to minimize resistive losses. However, by making the TCO quite conductive, it also absorbs more light which lowers the performance of the solar cell. Due to the limiting performance of the TCO's, there is a relatively large loss of performance of the solar cell in this layer.

In order to improve the serial connection between neighboring photovoltaic cells in a photovoltaic module, several solutions are disclosed in the art, which solutions may involve a metal grid. However, due to the shadowing caused by this metal grid some light is prevented from entering the absorber. This phenomenon is called “sun-block”.

Several solutions aimed towards improving interconnects within a photovoltaic module exist in the art. One solution is disclosed in EP2393122A1 another solution is disclosed in EP1868250A2. Both these solutions provide solutions which involves rather complex processing.

It is an object of the present invention to provide an improved photovoltaic module. A further object is to provide a photovoltaic module with an improved interconnection structure. An additional object of the invention is to provide a method for producing an improved photovoltaic module.

### GENERAL DESCRIPTION OF THE INVENTION

One or more of the above objects, and further possible objects that can be construed from the disclosure below, are met by a first aspect of the invention constituted by a method for producing a photovoltaic module. The method comprise depositing a contact layer on a substrate, forming a first gap through the contact layer, such that a first contact and a second contact are defined and isolated from each other by the first gap and have sidewalls facing each other. The first contact is a bottom contact for a first photovoltaic cell and the second contact is a bottom contact for a second photovoltaic cell. The method further comprises depositing a photovoltaic stack on the substrate, forming a second gap through the photovoltaic stack, parallel to and at least partly overlapping the first gap, such that a gap in the photovoltaic stack between the first photovoltaic cell and the second photovoltaic cell is formed, and a contact region of the upper side of the second contact becomes accessible from above. The second gap is arranged such that at least a part of the sidewall of the first contact, opposite and facing the sidewall of the second contact, is covered by the photovoltaic stack. The method further comprises, forming a contact finger extending from the top of the photovoltaic stack of the first photovoltaic cell to the contact region of the second contact that is accessible from above, whereby the first photovoltaic cell and the second photovoltaic cell becomes connected in series.

The above objects and further possible objects are further met by a second aspect of the invention constituted by a photovoltaic module. The photovoltaic module comprises a contact layer on a substrate, a first gap through the contact layer, wherein a first contact and a second contact are defined and isolated from each other by the first gap and have sidewalls facing each other. The first contact is a bottom contact for a first photovoltaic cell and the second contact is a bottom contact for a second photovoltaic cell. The photovoltaic module further comprises a photovoltaic stack on the substrate, and a second gap through the photovoltaic stack, parallel to and overlapping the first gap such that a gap is formed in the photovoltaic stack between the first photovoltaic cell and the second photovoltaic cell, and a contact region of the upper side of the second contact becomes accessible from above. The second gap is arranged such that at least a part of the sidewall of the first contact, opposite and facing the sidewall of the second contact, is covered by the photovoltaic stack. The photovoltaic module further comprises a contact finger extending from the top of the photovoltaic stack of the first photovoltaic cell to the contact region of the upper side of the second contact that is accessible from above, whereby the first photovoltaic cell and the second photovoltaic cell becomes connected in series.

The photovoltaic module according to the second aspect provides an improved photovoltaic module, since the contact fingers provide a connection with low resistivity and low sunblock. Furthermore, the photovoltaic module according to the second aspect provides an efficient structure for series connection of photovoltaic cells.

Additional or alternative features of the first aspect are described below.

The steps of forming the second gap through the photovoltaic stack may comprise forming a second groove through the photovoltaic stack that at least partly overlaps the first gap, and forming a second hole through the photovoltaic stack, wherein the second hole at least partly overlaps the second groove. This allows for easier routing of the contact finger since a larger region of the second contact becomes accessible. Furthermore, the contact area of the contact finger on the second contact generally contributes to a low resistance of the interconnection using metal fingers.

The step of forming a first gap through the contact layer may comprise forming a first groove through the contact layer, forming a first hole through the contact layer, wherein the first hole at least partly overlaps the first groove. This means that the first hole defines a region for connection of the contact finger between the first photovoltaic cell and the second photovoltaic cell, and the photovoltaic stack need not cover the sidewall of the first groove in the first contact but may instead fill the first hole. In this case, the contact finger becomes isolated from the first contact by means of the photovoltaic stack near the transition from the top contact to the first gap.

The first hole and the second hole are adjacent to each other. This means that the length of the contact finger is as short as possible, whereby the resistance of the contact finger is minimized. Another advantage related to manufacturing is that it is easy to route straight lines.

A first center point of the first hole and a second center point of the second hole may lie on a center line which is substantially perpendicular to the first groove and the second groove. This has the effect that the length of the contact finger is as short as possible, minimizing the resistance of the contact finger. This has also the effect that the length of the contact finger in the first groove is short.

The forming of a contact finger may be configured to form the contact finger parallel to the center line. This may have the effect that the length of the contact finger is as short as possible.

The forming of the first groove and the first hole may be performed simultaneously. This simultaneous forming of the first groove and the first hole means that no precise re-positioning of the substrate is required between the formation of the first groove and the first hole.

The forming of the first groove and the first hole may be performed simultaneously using mechanical means. This allows for easy manufacturing of the photovoltaic module. The mechanical means may be milling, laser etching, or scribing.

The depositing of a photovoltaic stack on the substrate may comprise forming a CIGS stack with a ZAO top layer as a top contact. The ZAO top layer provides a top contact with low resistance, and if this is combined with contact fingers the thickness of the ZAO layer may be reduced, thereby allowing more light to enter the CIGS stack.

The depositing of a photovoltaic stack on the substrate may comprise forming a CIGS stack with a transparent conductive oxide (TCO) top layer as a top contact. The TCO top layer provides a top contact with low resistance, and if this is combined with contact fingers the thickness of the TCO layer may be reduced, thereby allowing more light to enter the CIGS stack.

Below, additional or alternative features of the second aspect are presented.

The second gap through the photovoltaic stack may comprise a second groove and a second hole. The second hole may at least partly overlap the second groove. This allows for easy routing of the contact finger since a larger region of the second contact becomes accessible. Furthermore, increasing the contact area between the contact finger and the second contact generally contributes to a low resistance.

The first gap in the contact layer may comprise a first groove through the contact layer, and a first hole through the contact layer, wherein the first hole at least partly overlaps the first groove. This means that the first hole defines a region for the connection with the contact finger between the first photovoltaic cell and the second photovoltaic cell, and the photovoltaic stack need not cover the sidewall of the first contact in the first groove but may instead fill the first hole. In this case, the first hole filled with the photovoltaic stack provides an isolated region for routing the contact finger from the top contact of the first photovoltaic cell to the second contact of the second photovoltaic cell.

The first hole and the second hole may be adjacent to each other. This means that the length of the contact finger may be as short as possible, whereby the resistance in the contact finger decreases. Another advantage with this is that efficient manufacturing may become possible.

A first center point of the first hole and a second center point of the second hole may lie on a center line perpendicular to the first groove and the second groove. This has the effect that the length of the contact finger may be as short as possible and thereby the resistance may be minimized.

The contact finger may be a metal finger arranged in parallel with the center line. This may allow a short metal finger that decreases the resistance of the contact finger.

The photovoltaic stack may comprise a CIGS structure with a ZAO top contact. The ZAO top layer provides a top contact with low resistance, and if this is combined with contact fingers the thickness of the ZAO layer may be reduced, thereby allowing more light to enter the CIGS stack.

### BRIEF DESCRIPTION OF THE DRAWINGS

FIG. 1 illustrates a perspective view of a photovoltaic module according to a first embodiment of the invention,

FIG. 2a)-f) illustrate an embodiment of a method for producing a photovoltaic module according to the first embodiment in cross sectional and top view,

FIG. 3a)-c) illustrate different embodiments of a first gap in cross sectional and top views,

FIG. 4a)-c) illustrate different embodiments of a second gap in cross sectional and top views,

FIG. 5 illustrates in a perspective view of a photovoltaic module according to a third embodiment of the invention,

FIG. 6a)-f) illustrates in cross sectional and top views an embodiment of a method for producing a photovoltaic module according to the third embodiment,

FIG. 7 is a flowchart illustrating an embodiment of a method for producing a photovoltaic module according to the invention, and

FIG. 8 is a cross sectional view of a CIGS photovoltaic stack.

### DETAILED DESCRIPTION OF EMBODIMENTS OF THE INVENTION

The inventors have devised a way to interconnect photovoltaic cells in a photovoltaic module, which may require fewer mechanical operations and simultaneously decreases the dead-area of the photovoltaic module. In this detailed description the novel interconnects structure is described with reference made to a Cu(In,Ga)Se₂ photovoltaic stack, commonly designated a CIGS photovoltaic stack, but the inventive idea may also be used in other photovoltaic stacks that utilize thin film technology.

In the following positional terms such as “above”, “below”, “top”, and “bottom” etc. are used to aid in the understanding of the invention and merely describe relative position between elements. The skilled person understands that these relationships can be reversed.

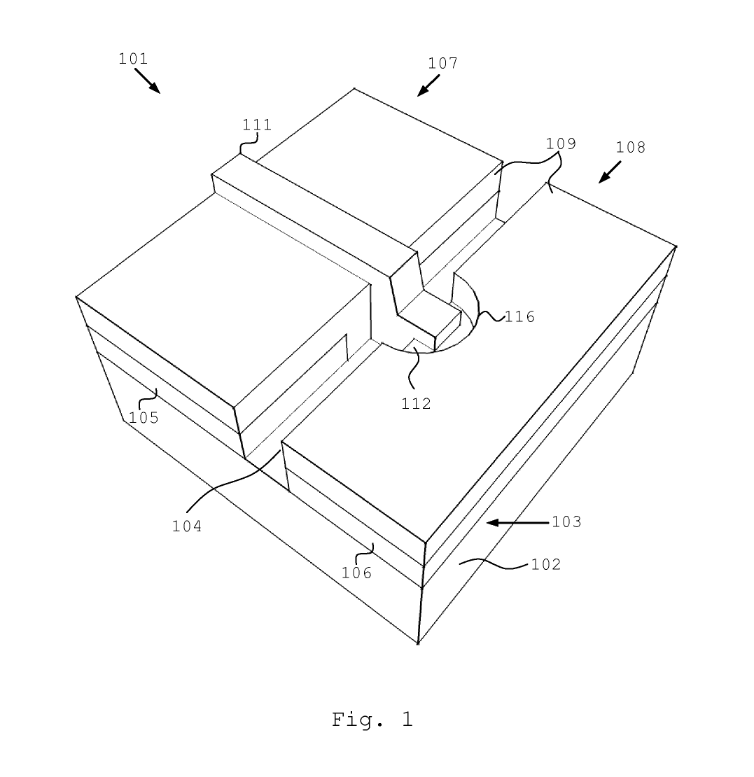

A first embodiment of the present invention, a photovoltaic module, generally designated 101, is shown in FIG. 1. The photovoltaic module 101 comprises a substrate 102. The substrate 102 may be a sheet of glass or another suitable material that provides sufficient isolation and suitable surface properties.

A contact layer 103 is arranged on the substrate 102. The contact layer 103 may comprise a layer of molybdenum (Mo) that has been deposited on the substrate 102. A first gap 104 is provided in the contact layer 103. This first gap 104 forms and defines a first contact 105 and a second contact 106 in the contact layer 103. The first contact 105 is a bottom contact for a first photovoltaic cell 107, and the second contact 106 is a bottom contact for a second photovoltaic cell 108. The first gap 104 extends through the thickness of the contact layer 103 such that the first contact 105 and the second contact 106 are isolated from each other.

A photovoltaic stack 109 is provided on each of the first contact 105 and the second contact 106. This photovoltaic stack 109 may comprise a CIGS stack with a transparent top contact of ZAO. Such a CIGS stack is described in the following with reference made to FIG. 8. This photovoltaic stack 109 on the first contact 105 forms a first photovoltaic cell 107, and on the second contact 106 forms a second photovoltaic cell 108.

In order to achieve a higher voltage from the photovoltaic module, the first photovoltaic cell 107 and the second photovoltaic cell 108 are connected in series by means of a metal grid with contact fingers arranged on top of the photovoltaic stack 109. In FIG. 1 one contact finger 111 is illustrated. This contact finger 111 is connected to a top contact of the photovoltaic stack 109 on the first photovoltaic cell 107. This top contact may be a ZAO layer that is both conductive and transparent. In order to achieve a good series connection between the first photovoltaic cell 107 and the second photovoltaic cell 108, the contact finger 111 is connected to the top contact of the photovoltaic stack 109 on the first photovoltaic cell 107 and extends to a contact region 112 of the second contact 106. This means that the top contact of the first photovoltaic cell 107 is series connected to the second contact 106 of the second photovoltaic cell 108 by means of the contact finger 111. However, in order to avoid a short circuit in the first photovoltaic cell 107 due to the contact finger 111 in the first gap 104, a region of the photovoltaic stack 109 extends under the contact finger 111 to the substrate 102 in the region where the contact finger 111 extends over the first gap 104.

Since the photovoltaic stack 109 comprises a photovoltaic material that may be almost insulating due to semiconducting properties, the region of the photovoltaic stack 109 that extends to the substrate 102 under the contact finger 111 thereby effectively isolating the contact finger 111 from the first contact 105. In this way, a short circuit in the first photovoltaic cell 107 is avoided.

In order to avoid a short circuit in the second photovoltaic cell 108 near the second contact 106 it is important that the contact finger 111 is not in contact with the photovoltaic stack 109 of the second photovoltaic cell near the contact region 112.

The photovoltaic stack 109 is commonly formed by sputtering, evaporation, coating or the like if it is fabricated as a thin film. A common example of a thin film photovoltaic stack 109 is illustrated in FIG. 8. In this example the photovoltaic stack 109 comprises an absorber 801. The absorber may be, for example a Cu(In, Ga) (Se, S)₂ absorber, commonly referred to as a CIGS absorber. The photovoltaic stack 109 further comprises a buffer layer 802 made of, for example, CdS. And the photovoltaic stack 109 further comprises a first window layer 803 made of, for example, ZnO and a second window layer 804 made of, for example, ZAO, that is Al-doped ZnO (ZAO). The ZAO material is a good conductor and is frequently used as a top contact of the photovoltaic stack 109.

The contact finger 111 may be manufactured by means of evaporating an Al layer on a photoresist mask, and the pattern may be created by means of dissolving the photoresist in a solute, whereby a lift-off process is created and an Al pattern is formed. The use of photolithography allows high manufacturing precision.

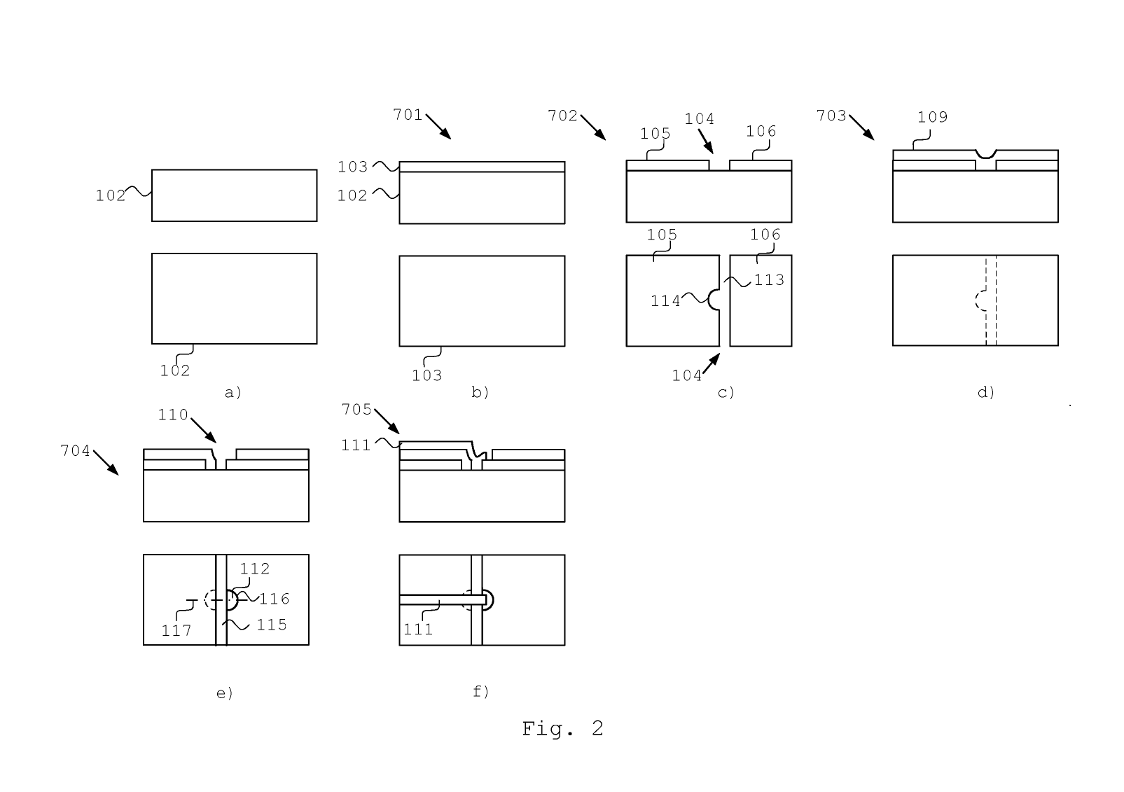

A second embodiment of the invention is partly shown in FIGS. 2a)-f). Features of the second embodiment that relate to features of the first embodiment by function have been given the same number indexing. The second embodiment provides a method for producing a photovoltaic module 101 according to the invention. In each of the subfigures a)-f) in FIG. 2, the top figure shows a cross section and the bottom figure shows a top view.

In the method outlined in FIG. 2 the following steps are performed:
a) Provide a suitable substrate 102, which substrate may for example be a glass substrate, a sheet of steel provided with an insulating coating, or a stainless steel strip.
b) Deposit a contact layer 103. This deposition may be performed by evaporation/sputtering or the like, a common material for the contact layer 103 is Mo.
c) Create a first gap 104 by means of, for example, laser patterning, scribing, etching or the like. This first gap 104 extends through the contact layer 103 and forms a first contact 105 and a second contact 106 electrically isolated from each other. This first gap 104 may comprise a first groove 113 and a first hole 114 formed with the above described method. Advantageously, the first groove 113 and the first hole 114 are formed in the same operation by means of, for example, controlling the scriber to manufacture the first hole 114 during the scribe of the first groove 113. A typical width of the first groove 113 is in the range from 10 um up to 100 um, but typically 50 um.
d) Deposit a photovoltaic stack 109 on the substrate 102 covering the first contact 105, the second contact 106, and the first gap 104. In one embodiment of the invention, the photovoltaic stack 109 is a CIGS structure, such as the one described above with reference made to FIG. 8.
e) The method further comprises a step of forming a second gap 110. The second gap 110 can be formed using the same methods as outlined above in c). In this embodiment the second gap 110 comprises a second groove 115 and a second hole 116. The second hole 116 and the first hole 114 may share a common center line 117 through their respective center. The second hole 116 and the first hole 114 may be positioned adjacent to each other. The second gap 110 extends through the photovoltaic stack 109 such that a first photovoltaic cell 107 and a second first photovoltaic cell 107 are formed on the first contact 105 and the second contact 106, respectively. A contact region 112 of the second contact 106 becomes accessible from above through this step e). In other words an opening in the photovoltaic stack 109 of the second photovoltaic cell 108 is created such that at least a part of the second contact 106 becomes accessible, wherein the opening is at least partly overlapping the second groove 115 when seen perpendicular to the opening.
f) The method further comprises forming a contact finger 111 on the photovoltaic stack 109 that extends from the top of photovoltaic stack 109 of the first photovoltaic cell 107 to the contact region 112 of the second contact 106 of the second photovoltaic cell 108. The contact finger 111 may be arranged parallel to the center line 117. This arrangement of the contact finger 111 causes the first photovoltaic cell 107 to become series connected to the second photovoltaic cell 108.

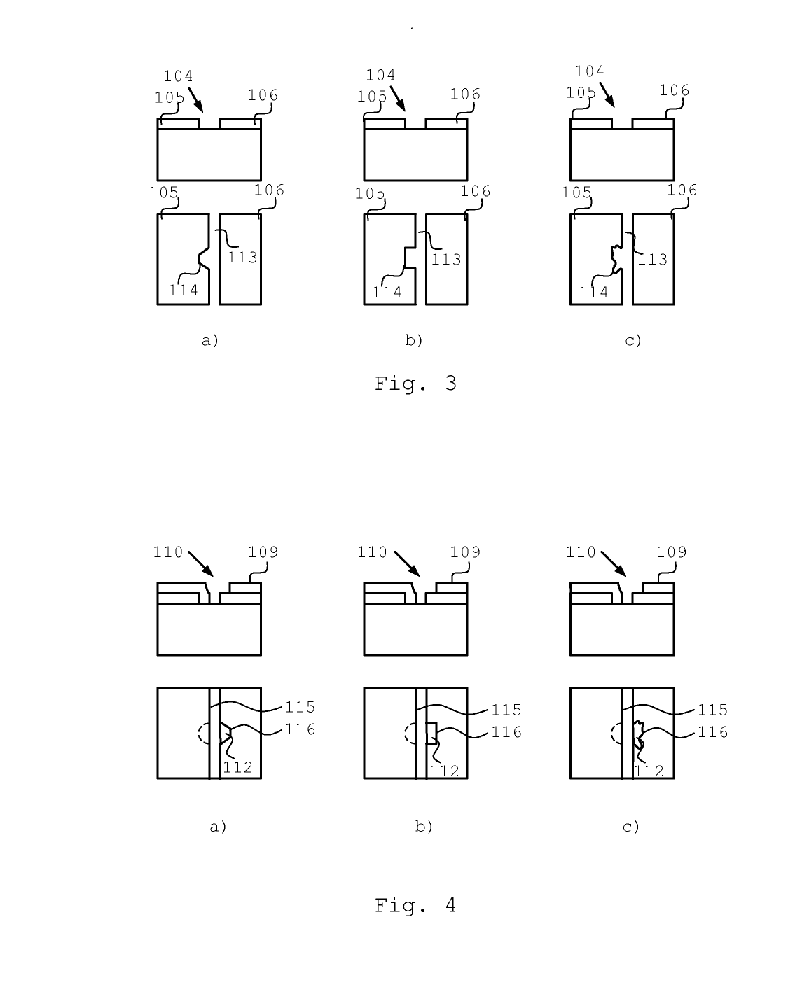

In FIG. 3a)-c) different alternative embodiments of the first gap 104 is disclosed. In FIG. 3a a first gap 104 is disclosed comprising a first groove 113 with an at least partly overlapping first hole 114 with the form of a parallelogram.

FIG. 3b illustrates an alternative first gap 104 with a first groove 113 and a partly overlapping first hole 114 with the form of a rectangle.

Finally, FIG. 3c illustrates a first gap 104 with a first groove 113 and a first hole 114 with the form of a non-uniform recess.

The embodiments disclosed in FIG. 3 illustrate the idea of providing a region for the photovoltaic stack 109 that extends through the contact layer 103 for providing isolation for the contact finger 111 for the connection from the first photovoltaic cell 107 to the second photovoltaic cell 108.

In FIG. 4a)-c) different alternative embodiments of the second gap 110 are disclosed. FIG. 4a shows a second gap 110 comprising a second groove 115 with an at least partly overlapping second hole 116 in the form of a parallelogram.

FIG. 4b illustrates a second gap 110 with a second groove 115 and a partly overlapping second hole 116 in the form of a rectangle.

Finally, FIG. 4c illustrates a second gap 110 with a second groove 115 and a second hole 116 in the form of a non-uniform opening in the photovoltaic stack 109.

One important feature disclosed in FIG. 4 is that the second hole 116 can have different shapes but all different embodiments provide a contact region 112 on the second contact 106 that is not covered with the photovoltaic stack 109.

The second hole 116 may advantageously be formed during the formation of the second groove 115. For example, if the second groove 115 is formed by means of a computer controlled scriber, the second hole 116 may be formed by programming the scriber to make an extra wiggle during the formation of the second groove 115.

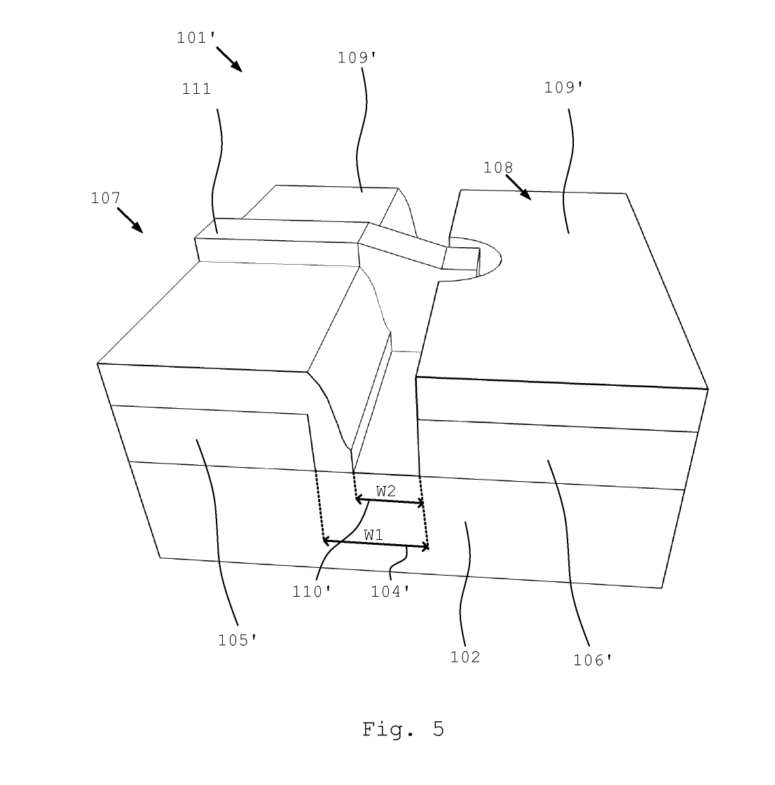

FIG. 5 discloses a third embodiment of a photovoltaic module 101′. This third embodiment differs from the photovoltaic module 101 of the first embodiment in that the first gap 104′ comprises a first groove 113′ with a width (W1) that is wider than the width (W2) of the second groove 115′ of the second gap 110′. This means that the photovoltaic stack 109′ will cover the sidewall of the first contact 105′, facing the first gap 104′, whereby the contact finger 111 will be isolated from the first contact 105′.

The photovoltaic stack 109 of the third embodiment may comprise a photovoltaic structure according to the above description and as shown in FIG. 8.

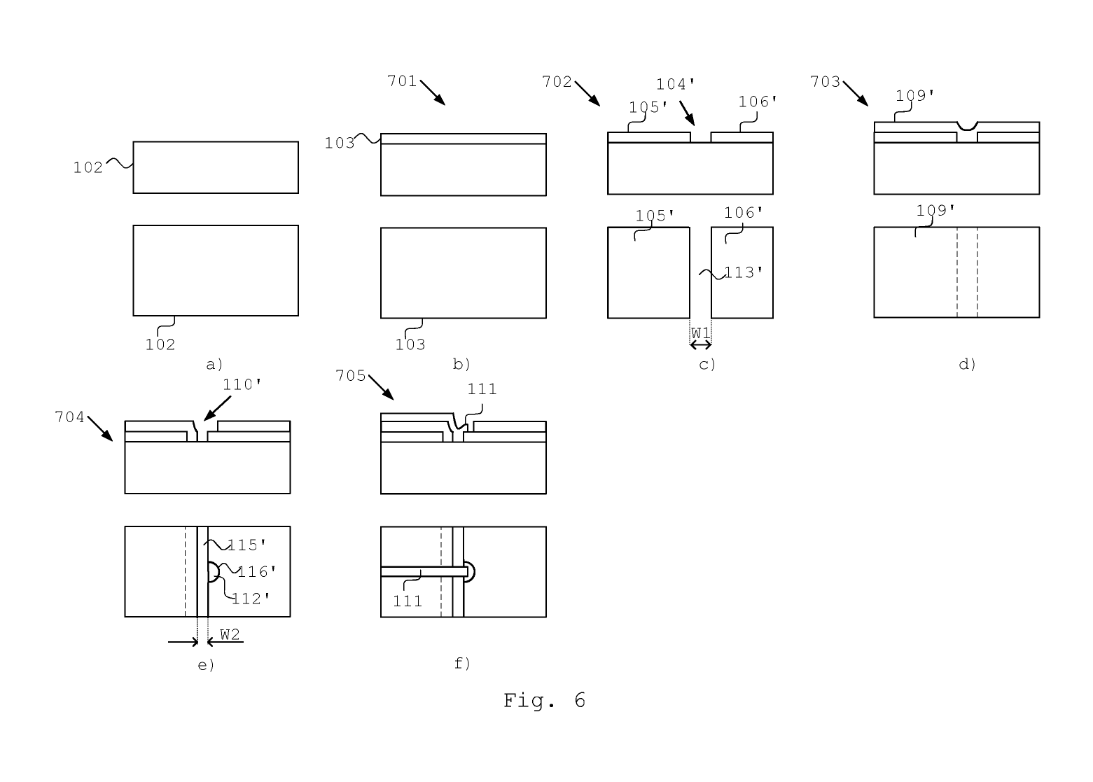

In FIG. 6a)-f) a method for producing a photovoltaic module 101′ according to the third embodiment is disclosed. Features of the third embodiment that relate to features of the first embodiment by function have been given the same number indexing, but with a prime.

This method starts with a substrate 102, which may be a sheet of glass or a metal strip for example.

In FIG. 6b, on the substrate 102′ is a contact layer 103′ deposited by means of for example sputtering, evaporation or the like. The contact layer 103′ may be a layer of molybdenum (Mo).

FIG. 6c) discloses a process for forming the first gap 104′ by means of scribing, laser etching, milling or the like. The first gap 104′ defines a first contact 105 and a second contact 106 that are electrically isolated from each other. In this embodiment the first gap 104′ comprises a first groove 113′, with width W1′, which extends through the contact layer 103′.

FIG. 6d) discloses a process of covering the substrate 102′, the first contact 105′, and the second contact 106′ with a photovoltaic stack 109′. The photovoltaic stack 109′ may be a CIGS photovoltaic stack as outlined above with reference made to FIG. 8.

In FIG. 6e) the second gap 110′ may be defined by means of scribing, laser etching or the like. During the formation of the second gap 110′ the process may be configured in such a way that only the photovoltaic stack 109′ is removed, if the tip of the scriber or the laser beam hits the photovoltaic stack 109′ on the contact layer 103′ only the photovoltaic stack 109′ will be removed. In this embodiment the second gap 110′ comprises a second groove 115, with a width W2, with a second hole 116′ that at least partly overlaps the second groove 115. In this embodiment the second groove 115′ is arranged within the first groove 113′ near the second contact 106′ with a width of W2<W1. Other solutions may be possible for example may W1=W2, wherein the second groove 115′ is provided a lateral offset such that the photovoltaic stack 109′ covers the sidewall of the first contact 105′ facing the first gap 104.

FIG. 6f) shows the step of forming the contact finger 111′ by means of for example a lift-off process. In this embodiment the contact finger 111′ extends from the top contact of the first photovoltaic cell 107, which in one embodiment may be a ZAO layer of a CIGS stack, to the second contact 106′ of the second photovoltaic cell 108′ in the region of the second hole 116′ that defines a bare region of the contact layer 103. Through this connection of the contact finger 111′ the first photovoltaic cell 107′ and the second photovoltaic cell 108′ becomes series connected.

Of course many other ways exists in the art for producing a contact finger 111, the above embodiment only discloses one example. Other methods such as screen-printing, wire gluing, wire bonding, ink-jet printing, or the like are of course also possible.

In order to obtain a low resistance for a photovoltaic module 101, 101′, it is advantageously to connect several fingers in parallel. In one embodiment, the distance between the fingers is in the range from 0.5 mm up to 2 mm.

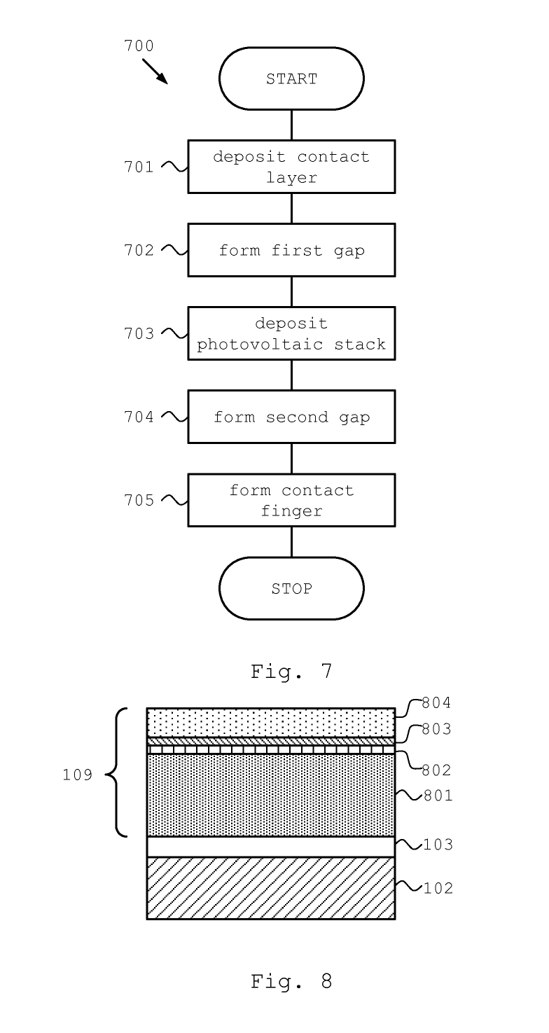

FIG. 7 shows an embodiment of the method for producing a photovoltaic module 101 in a flowchart. This method is described stepwise below:
701: Deposit the contact layer 103 on the substrate 102.
702: Form the first gap 104 in the contact layer 103.
703: Deposit the photovoltaic stack 109, which may be a CIGS stack.
704: Form the second gap 110 in the photovoltaic stack 109.
705: Form the contact finger 111.

Additional features that are disclosed in relation to the first embodiment can also be applied to the third embodiment.

The present inventors have devised a novel photovoltaic module 101 as well as a method for producing the same. One advantageous feature of this novel photovoltaic module 101 is the decrease of dead-area for a photovoltaic module. Dead-area is defined as the area of the photovoltaic module that is not involved in the photoelectric conversion. In a photovoltaic module according to the invention the amount of dead-area may be reduced from approximately 6% to 3%.

Another important feature of the novel method is that the method may reduce the number of scribes, in one embodiment the number of scribes may be reduced from the conventional three to two. The process of forming the second hole 116 may be performed by means of wiggling the scriber during the scribing operation of the second groove 115.

Another beneficial effect of the disclosed embodiments of a photovoltaic module is that the thickness of the ZAO layer may be reduced, which increases the efficiency of the photovoltaic module. However, the reduced ZAO thickness may require a denser configuration of the contact fingers in order to provide a low resistance. The disclosed prior art solutions all fail to deliver such a solution with a low degree of dead-area.

Another beneficial effect of the disclosed embodiments of the present invention is that the width of a photovoltaic cell may be increased from approximately 5 mm to 10 mm, due to the low resistance of the metal in the contact fingers, which means that the so called dead area decreases. A further advantage of wider photovoltaic cells is that the output voltage from each photovoltaic module decrease, which means that more photovoltaic modules can be connected in series, whereby the converter system operable for power conversion becomes cheaper and simpler.

Yet another beneficial feature of the disclosed embodiments of a method for producing a photovoltaic module is that the photovoltaic stack, except for the deposition of the contact layer 103, may be deposited in a sequence using the same equipment, which is advantageously since the whole sequence may be performed in vacuum.

In one embodiment of the method, the photolithographic definition of the metal grid is performed by means of a stepper. The stepper is configured to transfer a photolithographic mask pattern to the substrate as sub patterns. This embodiment may also involve an image recognition system being configured to control the stepper, such that the metal grid is correctly aligned with the substrate.

The above mentioned and described embodiments are only given as examples and should not be limiting. Other solutions, uses, objectives, and functions within the scope of the accompanying patent claims may be possible.

### ITEM LIST

101, 101′ photovoltaic module

102 Substrate

103 contact layer

104, 104′ first gap

105,105′ first contact

106,106′ second contact

107,107′ first photovoltaic cell

108,108′ second photovoltaic cell

109,109′ photovoltaic stack

110,110′ second gap

111 contact finger

112,112′ contact region

113,113′ first groove

114 first hole

115,115′ second groove

116,116′ second hole

117 center line

1. A method for producing a photovoltaic module, comprising:
depositing a contact layer on a substrate;
forming a first gap through the contact layer, such that a first contact and a second contact are defined and isolated from each other by the first gap and have sidewalls facing each other, wherein the first contact is a bottom contact for a first photovoltaic cell and the second contact is a bottom contact for a second photovoltaic cell;
depositing a photovoltaic stack on the substrate;
forming a second gap, through the photovoltaic stack, parallel and overlapping the first gap, such that a gap in the photovoltaic stack between the first photovoltaic cell and the second photovoltaic cell is formed, and a contact region of the upper side of the second contact becomes accessible from above, wherein the second gap is arranged such that at least a part of the sidewall of the first contact, opposite and facing the sidewall of the second contact, is covered by the photovoltaic stack;
forming a contact finger, extending from the top of the photovoltaic stack of the first photovoltaic cell to the contact region of the second contact that is accessible from above, whereby the first photovoltaic cell and the second photovoltaic cell becomes interconnected in series.

2. The method according to claim 1, wherein the step of forming the second gap through the photovoltaic stack comprises:
forming a second groove through the photovoltaic stack so that the second groove at least partly overlaps the first gap;
forming a second hole through the photovoltaic stack, wherein the second hole at least partly overlaps the second groove.

3. The method according to claim 2, wherein the step of forming a first gap through the contact layer comprising:
forming a first groove through the contact layer;
forming a first hole through the contact layer, wherein the first hole at least partly overlaps the first groove.

4. The method according to claim 3, wherein the first hole and the second hole are beside each other.

5. The method according to claim 4, wherein a first center point of the first hole and a second center point of the second hole lie on a center line perpendicular to the first groove and the second groove.

6. The method according to claim 5, wherein the forming of a contact finger is configured to form the contact finger parallel to the center line.

7. The method according to claim 2, wherein the forming of the first groove and the first hole are performed simultaneously.

8. The method according to claim 3, wherein the forming of the first groove and the first hole are performed simultaneously using mechanical means.

9. The method according to claim 1, wherein the depositing of a photovoltaic stack on the substrate, comprising forming a CIGS stack with a ZAO top layer as a top contact.

10. A photovoltaic module comprising:
a contact layer on a substrate;
a first gap through the contact layer, wherein a first contact and a second contact are defined and isolated from each other by the first gap and each have a sidewall facing the other, wherein the first contact is a bottom contact for a first photovoltaic cell and the second contact is a bottom contact for a second photovoltaic cell;
a photovoltaic stack on the substrate;
a second gap through the photovoltaic stack, parallel and overlapping the first gap, such that a gap in the photovoltaic stack between the first photovoltaic cell and the second photovoltaic cell is formed, and a contact region of the upper side of the second contact becomes accessible from above, wherein the second gap is arranged such that at least a part of the sidewall of the first contact, opposite and facing the sidewall of the second contact, is covered by the photovoltaic stack;
a contact finger extending from the top of the photovoltaic stack of the first photovoltaic cell to the contact region of the upper side of the second contact that is accessible from above, whereby the first photovoltaic cell and the second photovoltaic cell become connected in series.

11. The photovoltaic module according to the method of claim 9, wherein the second gap through the photovoltaic stack comprises:
a second groove;
a second hole, wherein the second hole at least partly overlaps the second groove.

12. The photovoltaic module according to claim 10, wherein the first gap in the contact layer comprises:
a first groove through the contact layer;
a first hole through the contact layer, wherein the first hole at least partly overlaps the first groove.

13. The photovoltaic module according to the method of claim 11, wherein the first hole and the second hole are adjacent to each other.

14. The photovoltaic module according to claim 12, wherein a first center point of the first hole and a second center point of the second hole lie on a center line perpendicular to the first groove and the second groove.

15. The photovoltaic module according to the method of claim 13, wherein the contact finger is a metal finger arranged parallel to the center line.

16. The photovoltaic module according to claim 12, wherein the photovoltaic stack comprises a CIGS structure with a ZAO top contact.
